(19) United States
(12) Patent Application Publication
(10) Pub. No.: US 2025/0240952 A1
(43) Pub. Date: Jul. 24, 2025

(54) MEMORY DEVICE AND METHOD OF FABRICATING THE SAME

(71) Applicant: Winbond Electronics Corp., Taichung City (TW)

(72) Inventors: Wen-Chieh Tsai, Taichung City (TW); Kun-Che Wu, Taichung City (TW)

(73) Assignee: Winbond Electronics Corp., Taichung City (TW)

(21) Appl. No.: 18/624,127

(22) Filed: Apr. 2, 2024

(30) Foreign Application Priority Data
Jan. 19, 2024 (TW) 113102302

(51) Int. Cl. H10B 41/35; H01L 29/423; H01L 29/66

(52) U.S. Cl. CPC H10B 41/35; H10D 30/0411; H10D 30/6892

(57) ABSTRACT

A memory device includes a substrate, a plurality of word lines, a select gate, and a dummy word line. The word lines are located above the substrate. The select gate is located on one side of the word lines. The dummy word line is located between the word lines and the select gate. A first gap between the word lines has a first gap width. A second gap between the dummy word line and an edge word line of the word lines has a second gap width. A third gap between the dummy word line and the select gate has a third gap width. A ratio of the third gap width to the first gap width is between 0.95 and 1.05.

### CROSS-REFERENCE TO RELATED APPLICATION

This application claims the priority benefit of Taiwan application serial no. 113102302, filed on Jan. 19, 2024. The entirety of the above-mentioned patent application is hereby incorporated by reference herein and made a part of this specification.

### BACKGROUND

### Technical Field

The disclosure relates to a semiconductor device and a method of fabricating the same, in particular, relates to a memory device and a method of fabricating the same.

### Description of Related Art

With the advancement of science and technology, various electronic products are developing towards the trend of being light, thin, short, and small. The critical dimensions of memory devices are also gradually shrinking, making the photolithography process increasingly difficult. In the conventional lithography process, methods to reduce critical dimensions include the use of optical elements with larger numerical apertures, the use of shorter exposure wavelengths (e.g., EUV), or the use of interface media other than air (such as water immersion).

It is known that the resolution of the conventional lithography processes is approaching the theoretical limit, so the self-aligning double patterning method has been adapted to overcome the optical limit and to further improve the integration density of memory devices. However, at present, since the pattern densities at the center and edge of the array region are different, the etching process will face a loading effect, which will lead to inconsistent contours of the memory cells at the center and edge of the array region, and electrical problems thereby occur.

### SUMMARY

The disclosure provides a memory device including a substrate, a plurality of word lines, a select gate, and a dummy word line. The word lines are located above the substrate. The select gate is located on one side of the word lines. The dummy word line is located between the word lines and the select gate. A first gap between the word lines has a first gap width. A second gap between the dummy word line and an edge word line of the word lines has a second gap width. A third gap between the dummy word line and the select gate has a third gap width. A ratio of the third gap width to the first gap width is between 0.95 and 1.05.

The disclosure further provides a method of fabricating a memory device including the following steps. A substrate is provided. A target layer is formed on the substrate. A sacrificial layer is formed on the target layer. A core layer is formed on the sacrificial layer. A plurality of gap walls are formed on a plurality of side walls of the core layer. The core layer is removed. The gap walls are treated as a mask and the sacrificial layer is patterned to form a patterned sacrificial layer. A hard mask layer is formed between the patterned sacrificial layer. The patterned sacrificial layer is removed. The hard mask layer is treated as a mask and the target layer is patterned to form a plurality of word lines, a dummy word line, and a select gate. The dummy word line is located between the word lines and the select gate.

Based on the above, in the embodiments of the disclosure, the loading effect is avoided during etching of the target layer, and the distances between the select gate and the word lines are accurately controlled. In this way, the gate induced drain leakage (GIDL) effect caused by the gate string, the select gate leakage current and electrons which are injected into the floating gate corresponding to the word line adjacent to the select gate are slowed down or suppressed.

### BRIEF DESCRIPTION OF THE DRAWINGS

FIG. 1 is a schematic cross-sectional view of a memory device according to an embodiment of the disclosure.

FIG. 2A is a top view of a memory device according to an embodiment of the disclosure.

FIG. 2B is an enlarged view of a partial region of FIG. 2A.

FIG. 3A to FIG. 3I are top views of a method of fabricating a memory device according to an embodiment of the disclosure.

FIG. 4A to FIG. 4F and FIG. 4G respectively are cross-sectional views of FIG. 3A to FIG. 3F and FIG. 3I taken along the line IV-IV.

### DESCRIPTION OF THE EMBODIMENTS

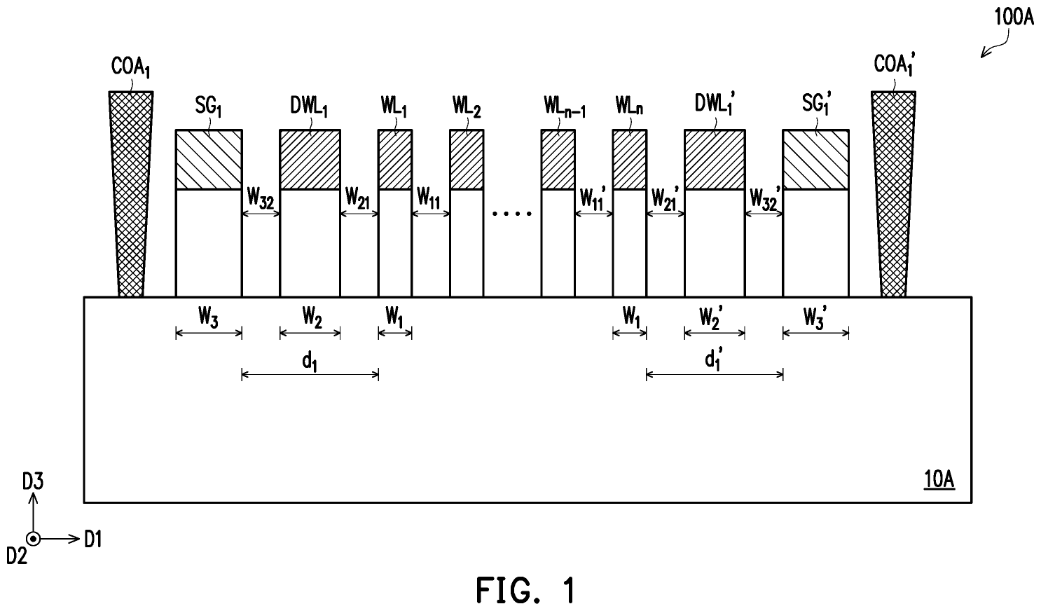

Refer to FIG. 1, a memory device 100A provided in the embodiments of the disclosure is formed on a substrate 10A. The memory device 100A is, for example, a NAND flash memory. The memory device 100 may include a plurality of word lines WL₁, WL₂ . . . . WLₙ₋₁, and WLₙ, a plurality of dummy word lines DWL₁ and DWL₁′, and a plurality of select gates SG₁ and SG₁′. The select gate SG₁ is adjacent to a contact COA₁. The select gate SG₁′ is adjacent to a contact COA₁′. The contact COA₁ is connected to, for example, a source, and the contact COA₁′ is connected to, for example, a drain. The dummy word line DWL₁ is disposed between the select gate SG₁ and the word line WL₁. The dummy word line DWL₁′ is disposed between the select gate SG₁′ and the word line WLₙ.

The word lines WL₁ to WLₙ have approximately the same width W₁. The dummy word lines DWL₁ and DWL₁′ have widths W₂ and W₂′ respectively. The select gates SG₁ and SG₁′ have widths W₃ and W₃′ respectively. In some embodiments, the widths W₃ and W₃′ are approximately equal. The widths W₂ and W₂′ are approximately equal. The widths W₃ and W₃′ are greater than the widths W₂ and W₂, and the widths W₂ and W₂′ are greater than the width W₁. A ratio W₂/W₁ of the width W₂ to the width W₁ is, for example, between 1.1 and 2.5. A ratio W₂′/W₁ of the width W₂′ to the width W₁ is, for example, between 1.1 and 2.5.

A first gap width Wₙ is provided between the word lines among the word lines WL₁ to WLₙ. A second gap width W₂₁ is provided between the dummy word line DWL₁ and the word line WL₁. A second gap width W₂₁′ is provided between the dummy word line DWL₁′ and the word line WLₙ. A third gap width W₃₂ is provided between the select gate SG₁ and the dummy word line DWL₁. A third gap width W₃₂′ is provided between the select gate SG₁′ and the dummy word line DWLₙ′.

In this embodiment, the third gap widths W₃₂ and W₃₂′ and the second gap widths W₂₁ and W₂₁′ are equal to or substantially equal to the first gap width W₁₁, or are within an error range, such as ±5%, of a fabrication process. That is, a ratio W₃₂/W₂₁ (or W₃₂′/W₂₁′) of the third gap width W₃₂ (or W₃₂′) to the second gap width W₂₁ (or W₂₁′) is between 0.95 and 1.05. A ratio W₃₂/W₁₁ (or W₃₂′/W₁₁) of the third gap width W₃₂ (or W₃₂′) to the first gap width W₁₁ is between 0.95 and 1.05. A ratio W₂₁/W₁₁ (or W₂₁′/W₁₁) of the second gap width W₂₁ (or W₂₁′) to the first gap width W₁₁ is between 0.95 and 1.05. In some embodiments, the third gap width W₃₂ (or W₃₂′) is equal to the first gap width W₁₁. The second gap width W₂₁ (or W₂₁′) is equal to the first gap width W₁₁. In some other embodiments, the third gap width W₃₂ (or W₃₂′) and the second gap width W₂₁ (or W₂₁′) are equal to the first gap width W₁₁. The third gap width W₃₂ (or W₃₂′), the second gap width W₂₁ (or W₂₁′), and the first gap width W₁₁ are equal or substantially equal. Therefore, during an etching process of forming a first gap, a second gap, and a third gap, a loading effect may be reduced and uniformity of the etching process may be improved.

In the embodiments of the disclosure, by adjusting the widths W₂ and W₂′ of the dummy word lines DWL₁ and DWL₁′, a sufficiently large distance d1 may be provided between the select gate SG₁ and the word line WL₁, and a sufficiently large distance d1′ may be provided between the select gate SG₁′ and the word line WLₙ. Therefore, when the memory device 100A is programmed, a GIDL effect caused by a gate string, a select gate leakage current and electrons which are injected into a floating gate corresponding to the word line adjacent to the select gate may be slowed down or suppressed.

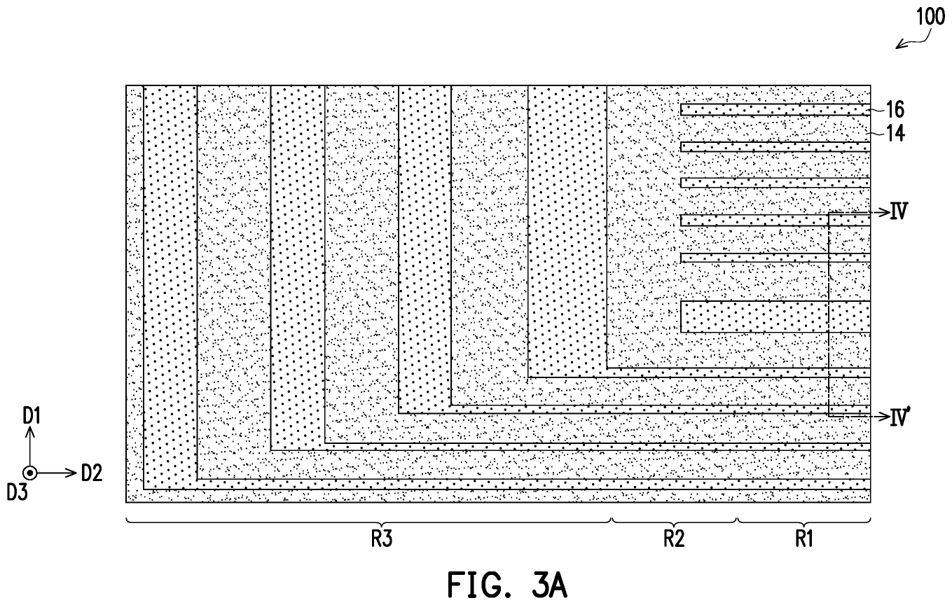

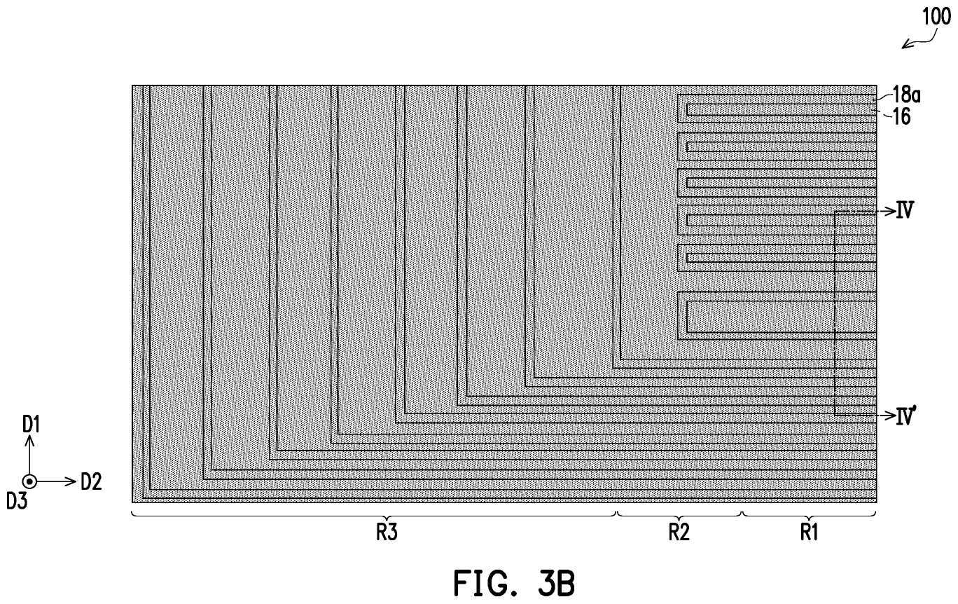

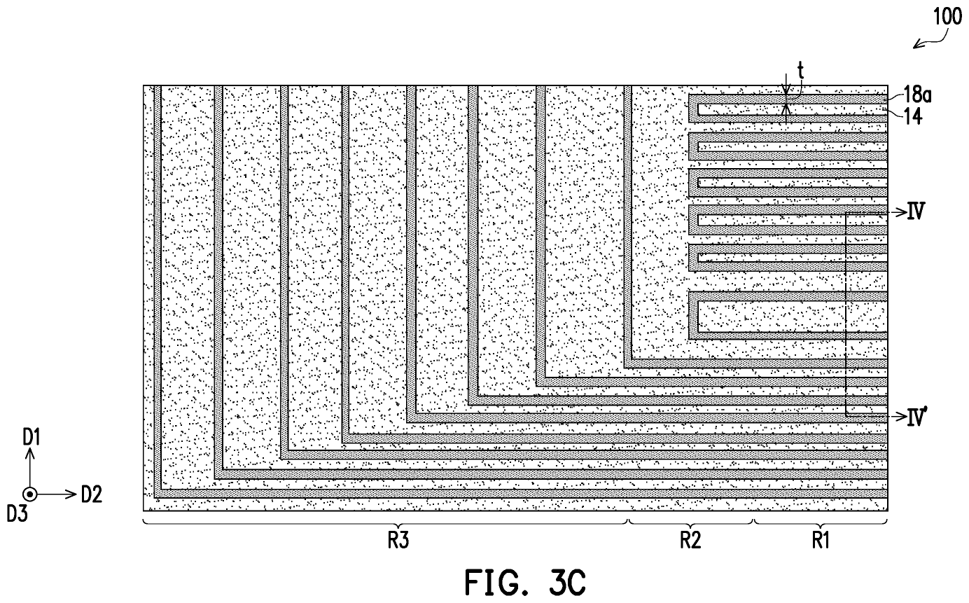

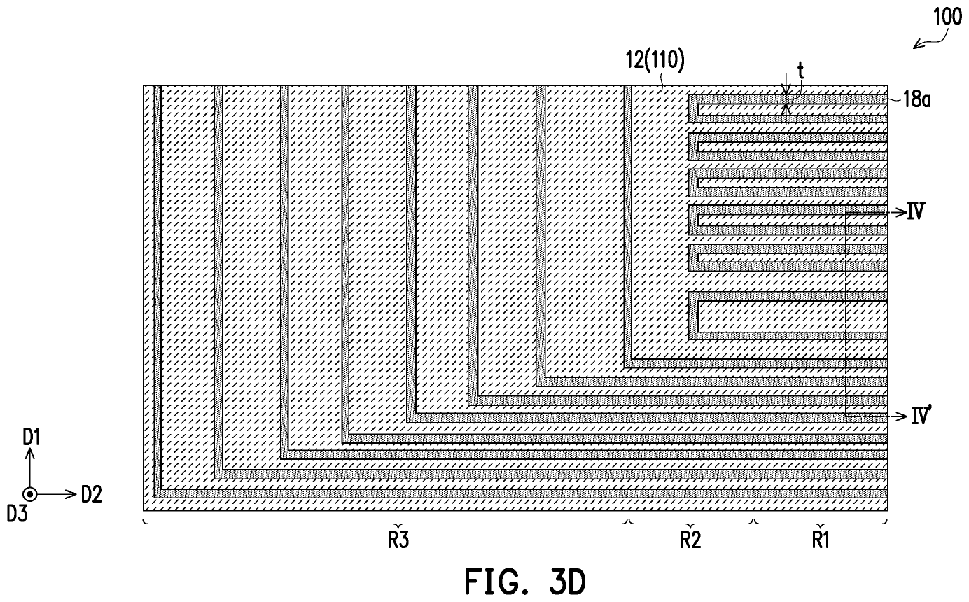

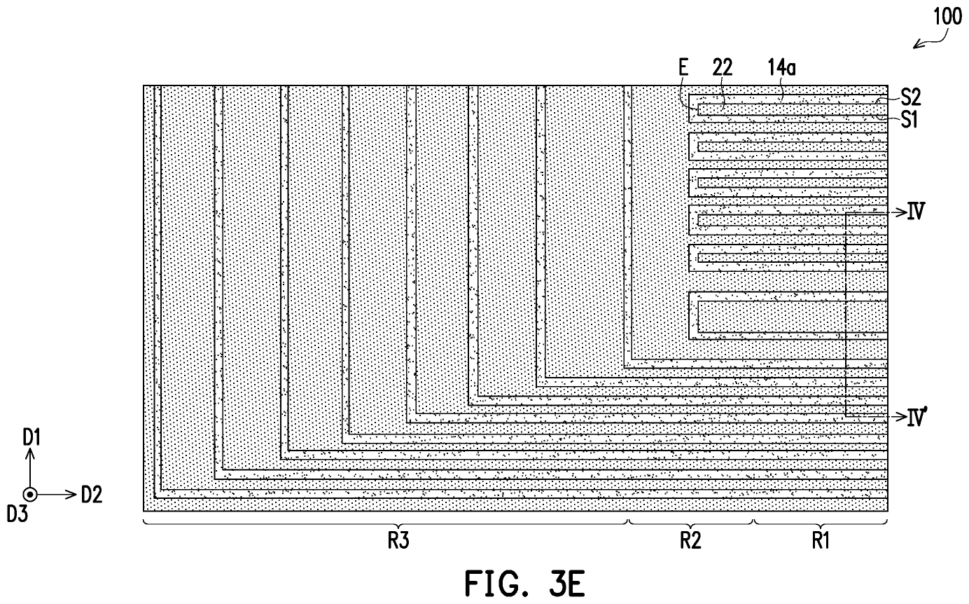

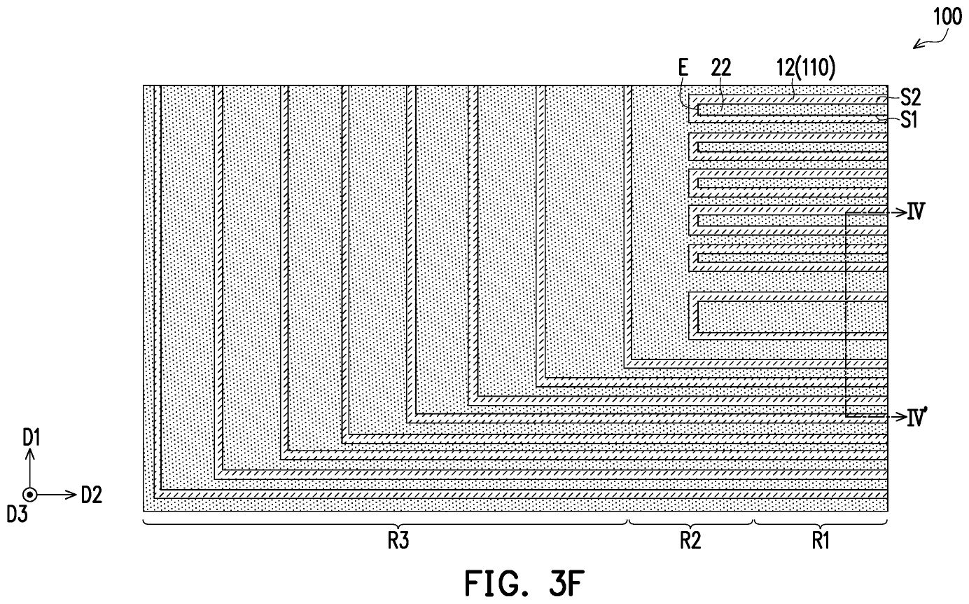

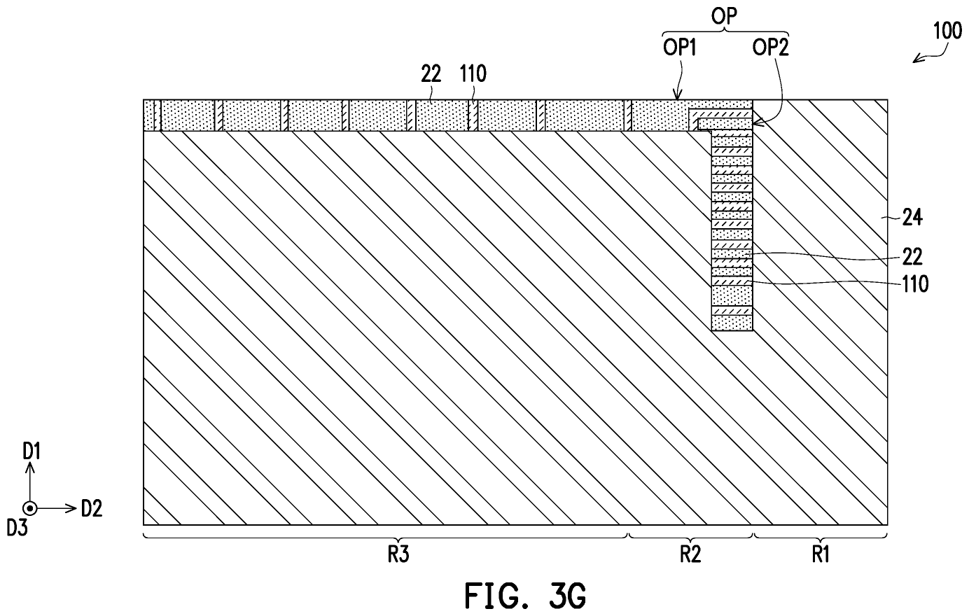

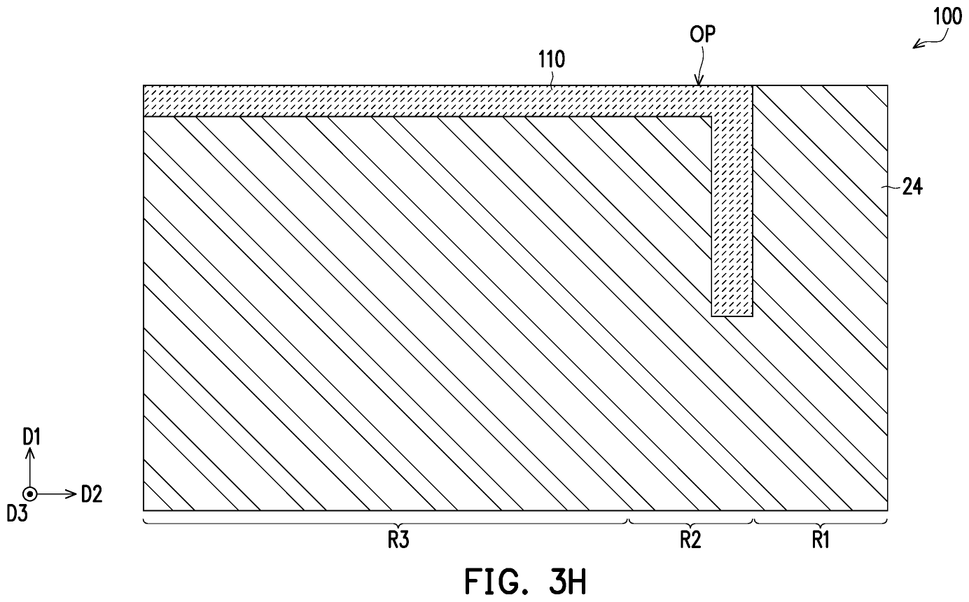

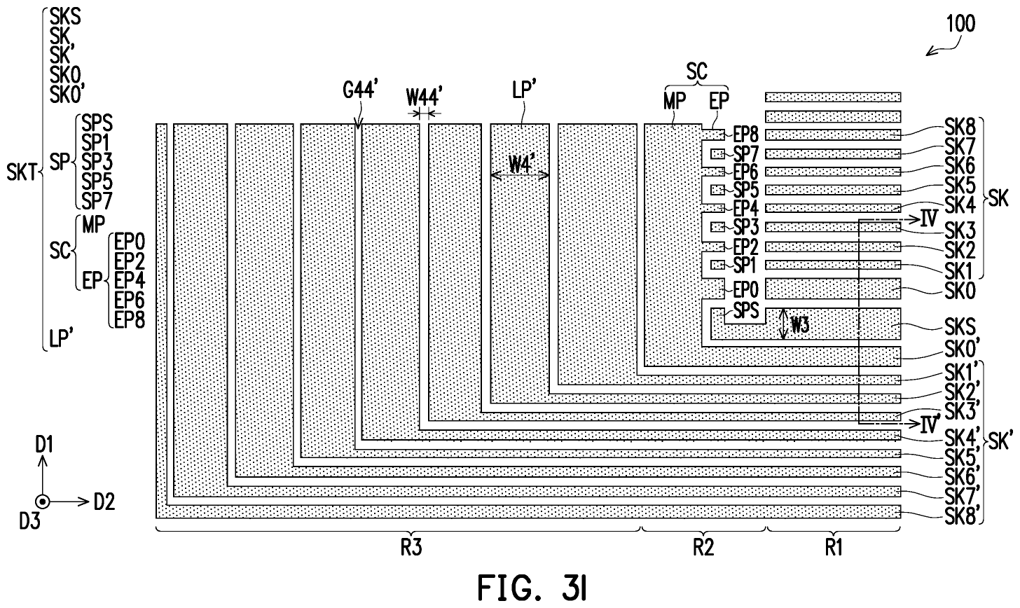

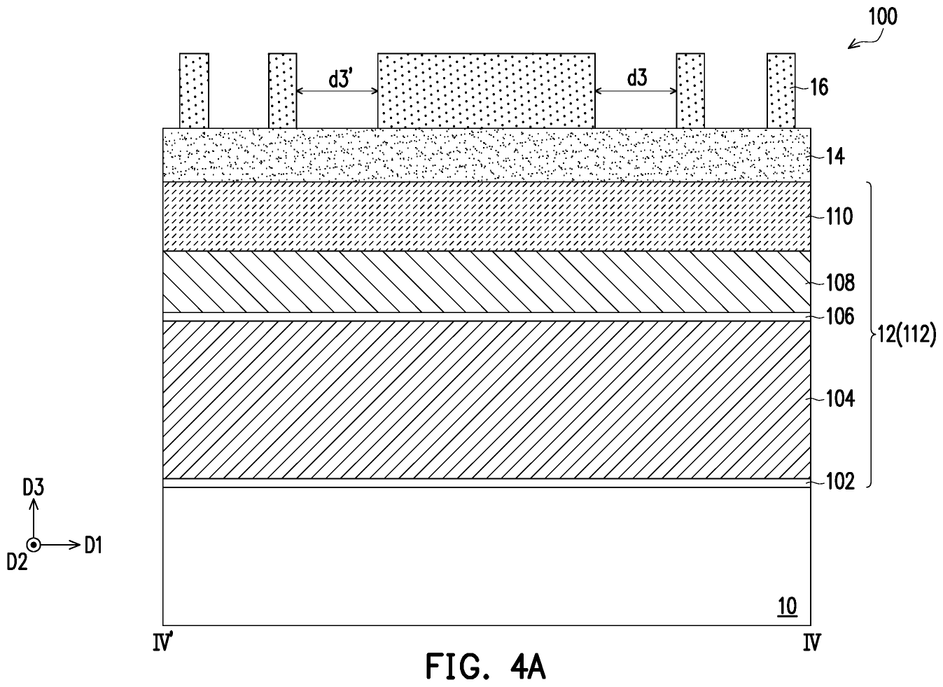

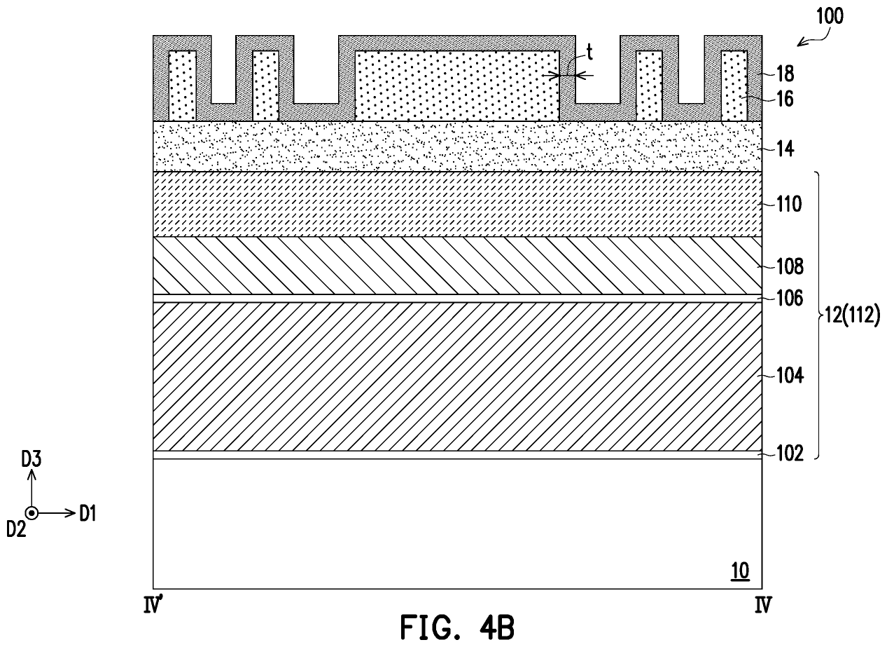

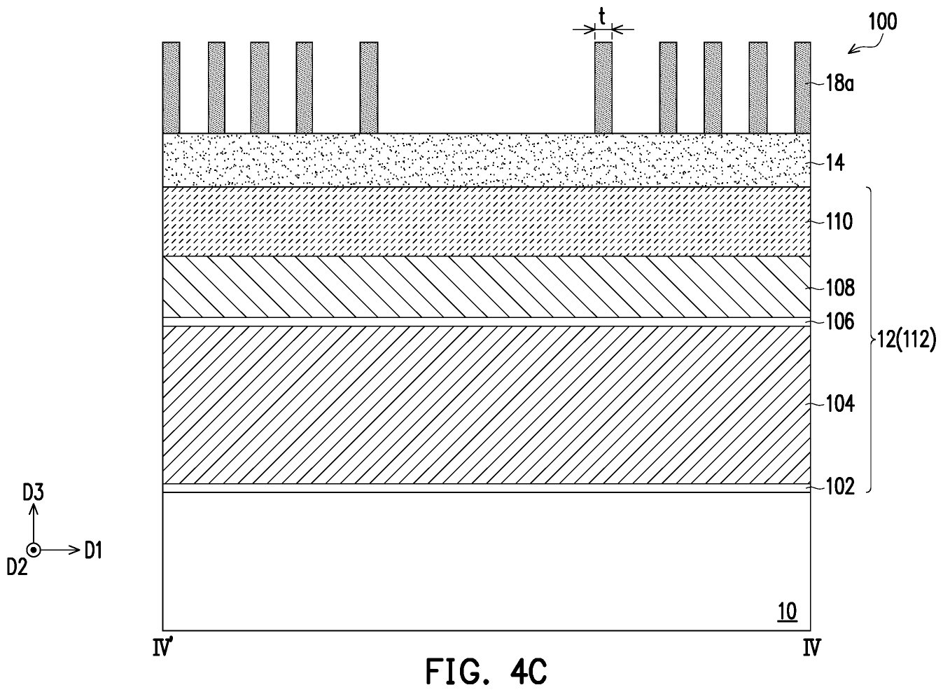

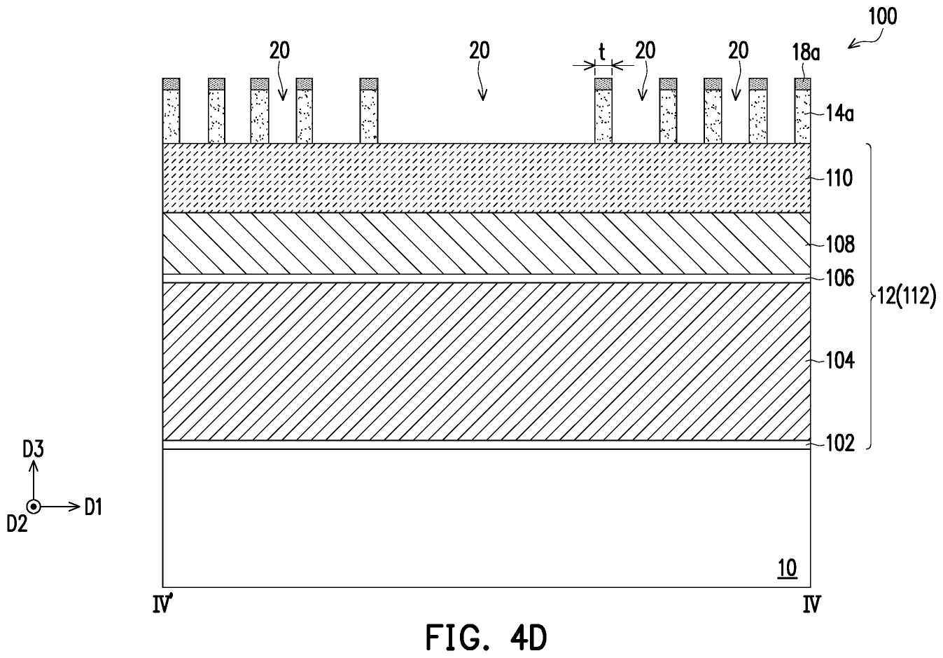

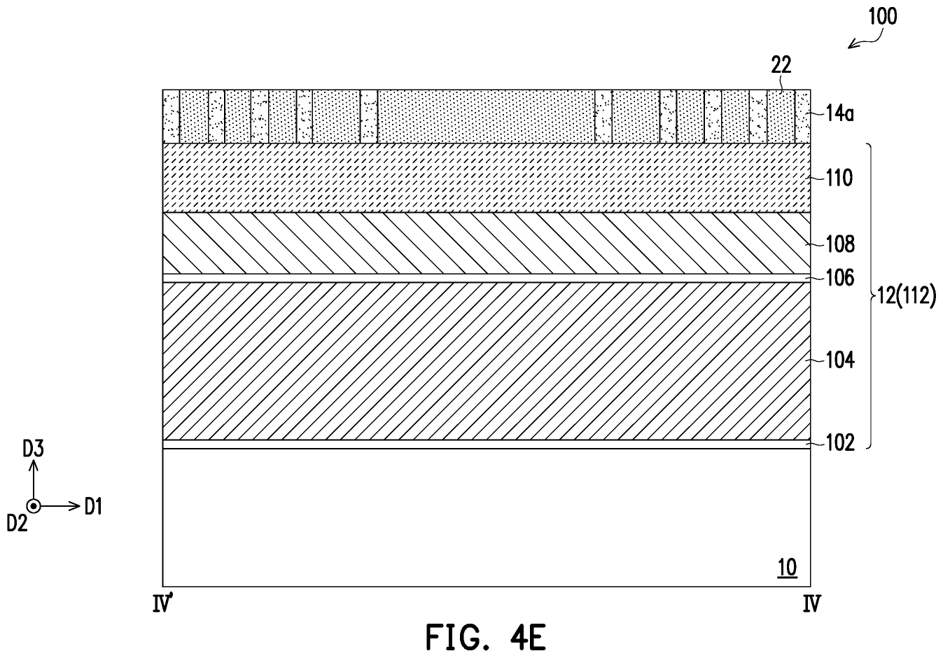

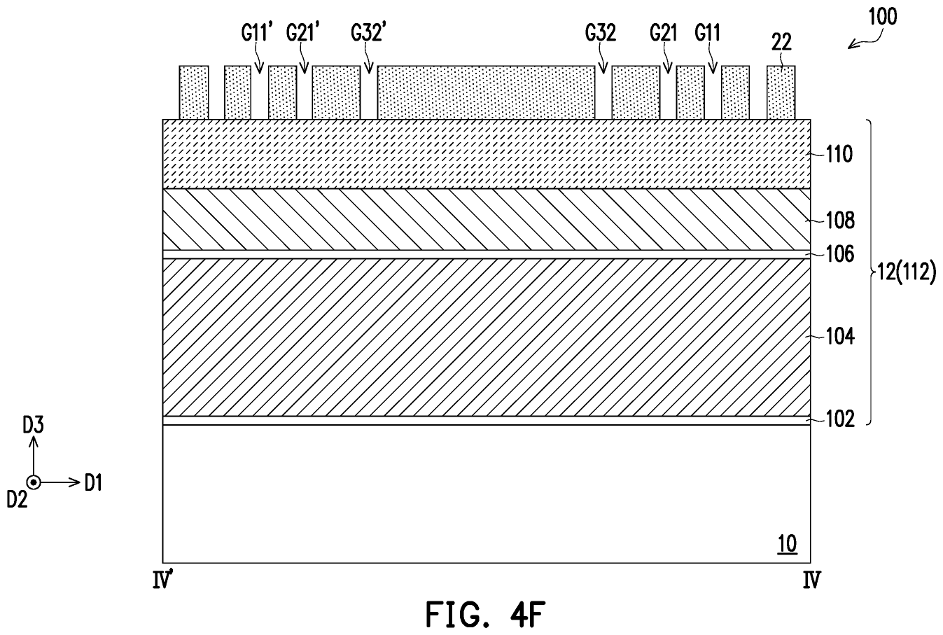

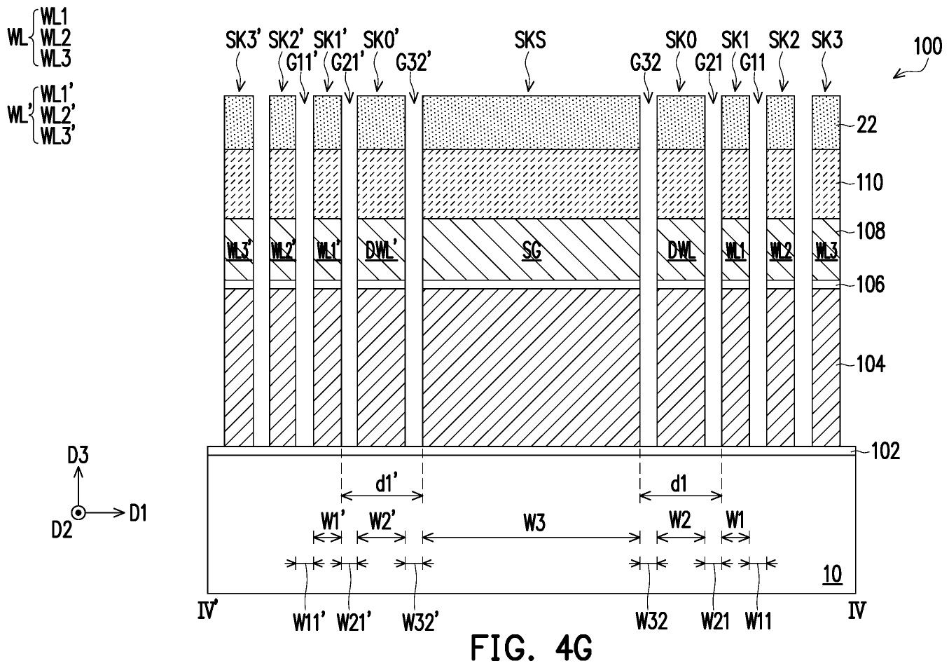

The embodiments of the disclosure provide a method of fabricating a memory device 100. Refer to FIG. 3A and FIG. 4A, a substrate 10 is provided. The substrate 10 may include an array region R1, a transition region R2, and a routing region R3. In this embodiment, the array region R1 may be a memory array region having one or a plurality of memory cells, and the routing region R3 may be a routing region having one or a plurality of word line contacts. The transition region R2 is between the array region R1 and the routing region R3. In an embodiment, the substrate 10 may be, for example, a semiconductor substrate, a semiconductor compound substrate, or a semiconductor-on-insulator (SOI) substrate. In this embodiment, the substrate 10 is a silicon substrate.

Next, a target layer 12 is formed on the substrate 10. The target layer 12 may be a stacked layer 112 stacked in a direction D3. To be specific, the stacked layer 112 may include a tunnel dielectric layer 102, a patterned floating gate layer 104, an inter-gate dielectric layer 106, a control gate layer 108, and a top cover layer 110 in order from bottom to top. A material of the tunnel dielectric layer 102 may be, for example, silicon oxide. The patterned floating gate layer 104 may include a conductive material, such as doped polysilicon, undoped polysilicon, or a combination thereof. The inter-gate dielectric layer 106 may be, for example, a composite layer composed of nitride/oxide/nitride/oxide/nitride (NONON), but the disclosure is not limited thereto, and this composite layer may also be a single layer or multiple layers. A material of the control gate layer 108 may include a conductive material, such as doped polysilicon, undoped polysilicon, or a combination thereof. In some other embodiments, the material of the control gate layer 108 may further include metal, such as W, TiN, or a combination thereof. A material of the top cover layer 110 may include a dielectric material, such as silicon nitride, silicon oxynitride, or a combination thereof.

A sacrificial layer 14 is formed on the target layer 12. The sacrificial layer 14 may include a conductive material, such as doped polysilicon, undoped polysilicon, or a combination thereof. A core layer 16 is formed on the sacrificial layer 14. The core layer 16 may include a carbide layer. In another embodiment, the core layer 16 may include the carbide layer and an anti-reflective layer. A material of the carbide layer may be, for example, spin-on-carbon (SoC). The anti-reflective layer may be located above the carbide layer, and a material of the anti-reflective layer may be, for example, silicon oxynitride. In a method of forming the core layer 16, a carbide material and an anti-reflective material are formed first, for example, and then a photoresist pattern is formed on the anti-reflective material through a photolithography process. In some embodiments, after the photoresist pattern is formed, a trimming process is also performed to reduce a width of the formed photoresist pattern. Thereafter, an etching process is performed to transfer a pattern of the photoresist pattern down to the anti-reflective material and carbide material. Afterwards, the photoresist pattern is removed, leaving the carbide layer and anti-reflective layer.

Refer to FIG. 3B and FIG. 4B, a gap wall material 18 is formed on a surface and sidewalls of the core layer 16 and the sacrificial layer 14. The gap wall material 18 includes an oxide, such as silicon oxide. The gap wall material 18 is, for example, a conformal layer having approximately a same thickness t.

Refer to FIG. 3C and FIG. 4C, an anisotropic etching process, such as a reactive ion etching process, is performed on the gap wall material 18 to remove part of the gap wall material 18 until a top surface of the core layer 18 is exposed, so as to form a gap wall 18a on the side wall of the core layer 18. Afterwards, a selective etching process is performed to remove the core layer 16 and expose the sacrificial layer 14.

Refer to FIG. 3D and FIG. 4D, the gap wall 18a is treated as a mask, an anisotropic etching process, such as a reactive ion etching process, is performed to remove the sacrificial layer 14 not covered by the gap wall 18a to form a patterned sacrificial layer 14a. A gap 20 is provided between the patterned sacrificial layer 14a.

Refer to FIG. 3E and FIG. 4E, a hard mask layer 22 is formed in the gap 20. The hard mask layer 22 is formed as follows, for example. A hard mask material is formed on the gap wall 18a and in the gap 20. The hard mask material includes an oxide, such as silicon oxide. The hard mask material may be formed via flowable chemical vapor deposition (FCVD). Afterwards, a planarization process, such as chemical mechanical polishing, is performed to remove the hard mask material on the gap wall 18a and the gap wall 18a, so as to expose the patterned sacrificial layer 14a and form the hard mask layer 22 in the gap 20.

Refer to FIG. 3F and FIG. 4F, a selective etching process is performed to remove the patterned sacrificial layer 14a and expose the top cover layer 110. In the top view of FIG. 3F, in the array region R1 and the transition region R2, the top cover layer 11 that is not covered by the hard mask layer 22 surrounds the hard mask layer 22. That is, the top cover layer 110 not covered by the hard mask layer 22 surrounds two sides S1, S2 and an end E of the hard mask layer 22.

Refer to FIG. 3G, a mask layer 24 is formed above the substrate 10. The mask layer 24 is, for example, a patterned photoresist layer. The mask layer 24 partially covers the array region R1, the transition region R2, and the routing region R3. The mask layer 24 has an opening OP, exposing the hard mask layer 22 in the routing region R3 and the transition region R2 and the top cover layer 110 that is not covered by the hard mask layer 22. The opening OP includes a first portion OP1 and a second portion OP2. The first portion OP1 extends in a direction D2 from the routing region R3 to the transition region R2. The second portion OP2 extends in a direction D1. The second portion OP2 is located at the end E of the hard mask layer 22 close to the array region R1 (shown in FIG. 3F).

Refer to FIG. 3H, a selective etching process is performed to remove the hard mask layer 22 exposed by the opening OP to expose the top cover layer 110.

Refer to FIG. 3I and FIG. 4G, the mask layer 24 is removed, and then a shearing process is performed. The shearing process uses the hard mask layer 22 as a mask and performs an anisotropic etching process to pattern the target layer 12. In this embodiment, the top cover layer 110, the control gate layer 108, the inter-gate dielectric layer 106, and the patterned floating gate layer 104 of the stacked layer 112 are patterned to form a patterned stacked layer SKT.

Refer to FIG. 3I, the patterned stacked layer SKT includes a plurality of patterned stacked layers SK, SK′, SKS, SK0, and SK0′ located in the array region R1. The patterned stacked layers SK, SK′, SKS, SK0, and SK0′ extend in the direction D2 and are arranged in the direction D1. FIG. 3I shows that the patterned stacked layers SK include patterned stacked layers SK1 to SK8, and the patterned stacked layers SK′ include patterned stacked layers SK1′ to SK8′.

Gaps G11, G11′, G21, G21′, G32, G32′, and G44′ are provided between the patterned stacked layers SK, SK′, SKS, SK0, and SK0′ of the patterned stacked layer SKT. The gaps G11, G11′, G21, G21′, G32, G32′, and G44′ in the embodiments of the disclosure correspond to the position of the gap wall 18a. Therefore, the disclosure belongs to a reverse tone dual patterning implement (reverse tone SADP implement). The gaps G11, G11′, G21, G21′, G32, G32′, and G44′ are formed by removing the patterned sacrificial layer 14a (shown in FIG. 4E and FIG. 4F), and a pattern of patterned sacrificial layer 14a is formed by the migration of the gap wall 18a (shown in FIG. 4C and FIG. 4E). Therefore, sizes of the gaps G11, G11′, G21, G21′, G32, G32′, and G44′ may be determined by the thickness t of the gap wall 18a. The gap wall 18a may be controlled to have the same or approximately the same thickness t through deposition and etching processes. Therefore, when the etching process is performed to remove the patterned sacrificial layer 14a and the target layer 12, since the width t of the patterned sacrificial layer 14a is approximately the same or similar, the loading effect may be lowered or avoided.

Refer to FIG. 3I, the patterned stacked layer SKT may further include a plurality of dummy pillars SP located in the transition region R2. The dummy pillars SP include, for example, SPS, SP1, SP3, SP5, and SP7 respectively corresponding to the patterned stacked layers SKS, SK1, SK3, SK5, and SK7. Viewed from the top view, a portion of each of the patterned stacked layers SKS, SK1, SK3, SK5, and SK7 is strip-shaped. Each of the dummy pillars SP1, SP3, SP5, and SP7 is in the shape of an island. The dummy pillar SPS is connected to the stacked layer SKS.

Refer to FIG. 3I, the patterned stacked layer SKT may further include a dummy comb SC located in the transition region R2. The dummy comb SC includes a body MP and a plurality of extending portions EP. The body MP extends in the direction D1. The extending portions EP are disposed on the same side of the body MP and are connected to the body MP. The extending portions EP include, for example, extending portions EP0, EP2, EP4, EP6, and EP8 extending in the direction D2, arranged in the direction D1, and respectively corresponding to the patterned stacked layers SK0, SK2, SK4, SK6, and SK8. In the direction D1, the extending portions EP and the dummy pillars SP are arranged in an alternating manner. A length L1 of each of the extending portions EP in the direction D2 is greater than a length L2 of each of the dummy pillars SP in the direction D2. Further, the dummy comb SC is connected to the patterned stack layer SK0′.

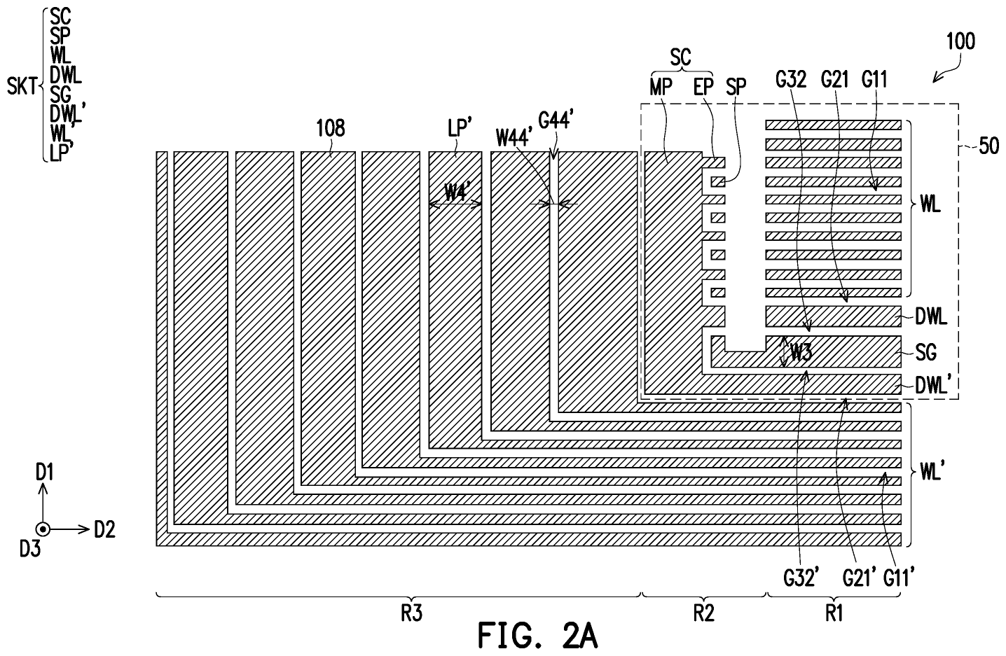

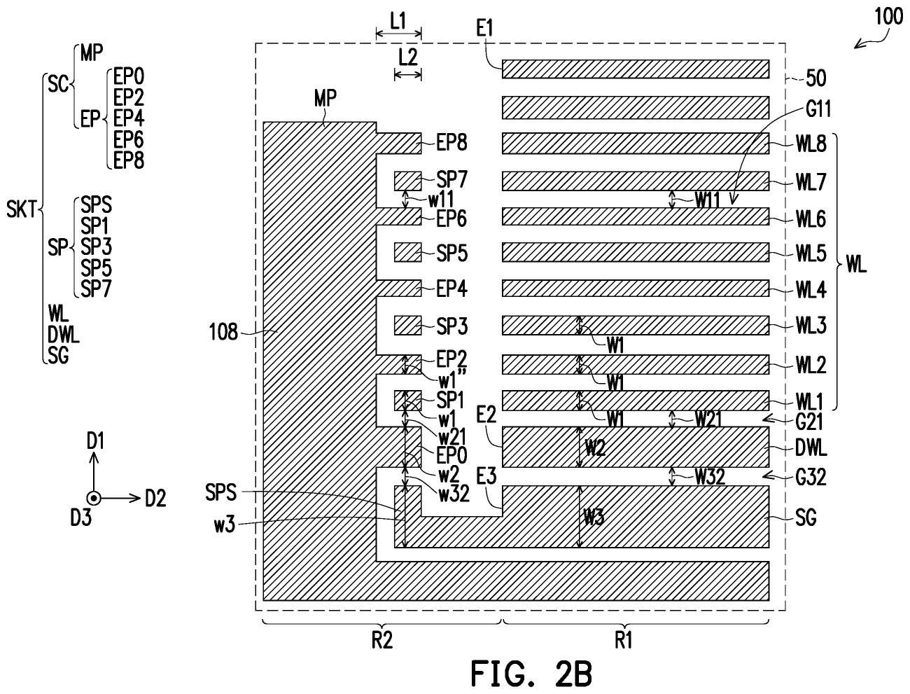

Refer to FIG. 3I, FIG. 2A, and FIG. 2B, FIG. 2A shows a top view of the control gate layer 108 of the patterned stacked layer SKT of FIG. 3I. FIG. 2B shows an enlarged view of a portion of a region 50 of FIG. 2A. The control gate layer 108 disposed on the patterned stacked layers SKS, SK0, SK0′, SK, and SK′ of the array region R1 act as the select gate SG, the dummy word lines DWL and DWL′, and the word lines WL and WL′, respectively. The control gate layer 108 disposed in the routing region R3 acts as a plurality of landing pads LP′ for pick ups of the word line WL′. In the embodiments of the disclosure, the select gate SG and the landing pads LP′ may be formed in the same etching process as the dummy word lines DWL and DWL′ and the word lines WL and WL′ without requiring additional lithography and etching processes for patterning.

Refer to FIG. 2B, the dummy comb SC and the dummy pillars SP are disposed in the transition region R2. The extending portions EP of the dummy comb SC and the control gate layer 108 of the dummy pillars SP are adjacent to ends E1 of the word lines WL, an end E2 of the dummy word line DWL, and an end E3 of the select gate SG. The control gate layer 108 of the dummy pillars SP may be in a square, rectangular, circular, or elliptical shape. Widths w1 and w3 of the control gate layer 108 of the plurality of dummy pillars SP in the direction D1 are substantially the same as the widths W1 and W3 of the corresponding word line WL₁ and the select gate SG, respectively.

Widths w1″ and w2 of the control gate layer 108 of the extending portions EP of the dummy comb SC in the direction D1 are substantially the same as the widths W₁ and W₂ of the corresponding word line WL₂ and the dummy word line DWL, respectively. Each of the dummy pillars SP is provided between adjacent extending portions EP. The first gap width W11, the second gap width W21, and the third gap width W₃₂ between adjacent patterned stacked layers SK corresponding to the gap widths w11, w21, and w32 between the adjacent dummy pillars SP and the extending portions EP are substantially the same.

Refer to FIG. 4G, the patterned stacked layers SKS, SK0, SK1, SK2, SK3, SK0′, SK1′, SK2′, and SK3′ include the tunnel dielectric layer 102, the patterned floating gate layer 104, the inter-gate dielectric layer 106, the control gate layer 108, and the top cover layer 110 in order from bottom to top. The control gate layer 108 of the patterned stacked layer SKS may act as the select gate SG. The control gate layer 108 of the patterned stacked layers SK1, SK2, SK3, SK1′, SK2′, and SKY may act as the word lines WL1, WL2, WL3, WL1′, WL2′, and WL3′. The control gate layer 108 of the patterned stacked layer SK0 between the patterned stacked layer SKS and the patterned stacked layer SK1 may act as the dummy word line DWL. Further, control gate layer 108 of the patterned stacked layer SK0′ between the patterned stacked layer SKS and the patterned stacked layer SK1′ may act as the dummy word line DWL′.

The width W3 of the select gate SG is greater than the width W2 of the dummy word line DWL and the width W2′ of the dummy word line DWL′ and is greater than the width W1 of each of the word lines WL1 to WL3 and the width W1′ of each of the word lines WL1′ to WL3′. The widths W2 and W2′ of the dummy word lines DWL and DWL′ may be respectively greater than the widths W1 and W1′ of the word lines WL1 to WL3 and WL1′ to WL3′. In some embodiments, the ratio W2/W1 of the width W2 to the width W1 is between 1.1 and 2.5, and the ratio W2′/W1′ of the width W2′ to the width W1′ is between 1.1 and 2.5.

The first gap G11/G11′ between the word lines WL/WL′ has the first gap width W11/W11′. The second gap G21/G21′ between the dummy word line DWL/DWL′ and the edge word line WL1/WL1′ of the word lines WL/WL′ has the second gap width W21/W21′. The third gap G32/G32′ between the select gate SG and the dummy word line DWL/DWL′ has the third gap width W32/W32′.

Refer to FIG. 3I and FIG. 2A, the landing pads LP′, the dummy pillars SP, and the dummy comb SC are formed in a way similar that of the patterned stack layer SK and include the tunnel dielectric layer 102, the patterned floating gate layer 104, the inter-gate dielectric layer 106, the control gate layer 108, and the top cover layer 110 in order from bottom to top. A width W4′ of each of the landing pads LP′ is greater than the width W₃ of the select gate SG. A fourth gap G44′ between the landing pads LP′ has a fourth gap width W44′.

Refer to FIG. 3I and FIG. 4G, in the embodiments of the disclosure, the fourth gap width W44′, the third gap widths W32 and W32′, and the second gap widths W21 and W21′ are equal to or substantially equal to the first gap widths W11 and W11′, or are within the error range, such as ±5%, of the fabrication process. That is, a ratio W44′/W11′ of the fourth gap width W44′ to the first gap width W11 (or W11′) is between 0.95 and 1.05. The ratio W32/W11 (or W32′/W11) of the third gap width W32 (or W32′) to the first gap width W₁₁ (or W11′) is between 0.95 and 1.05. The ratio W21/W11 (or W21′/W11′) of the second gap width W21 (or W21′) to the first gap width W11 (or W11′) is between 0.95 and 1.05. In some embodiments, the fourth gap width W44′ is equal to the first gap width W11′. In some embodiments, the widths W1 and W1′ of the word lines WL1 to WL3 and WL1′ to WL3′ are substantially equal to the fourth gap width W44′, the third gap widths W32 and W32′, the second gap widths W21 and W21′, and the first gap widths W11 and W11′, or are within the error range, such as ±5%, of the fabrication process.

Refer to FIG. 4A and FIG. 4G, in the embodiments of the disclosure, by controlling a distance d3/d3′ between the core layer 16 and the corresponding select gate SG/the corresponding word line WL1/WL′, the dummy word line DWL/DWL′ with a larger width W2/W2′ may be formed, so that a sufficient distance d1/d1′ is provided between the select gate SG and the word line WL1/WL1′. Therefore, when the memory device is programmed, the GIDL effect caused by the gate string, the select gate leakage current and electrons that are injected into the floating gate corresponding to the word line adjacent to the select gate may be slowed down or suppressed.

In the embodiments of the disclosure, the sizes of the gaps between the patterned stacked layer SKT is related to the thickness t (size) of the gap wall 18a, as shown in FIG. 4B to FIG. 4D. In terms of a fabrication process, compared to controlling the size of the core layer 16, the thickness t of the gap wall 18a may be more accurately controlled by changing the conditions of the etching process. Therefore, the sizes of the gaps between adjacent stacked layers of the patterned stacked layer SKT may be accurately controlled by adjusting the thickness t of the gap wall 18a. In other words, the distance d1 between the select gate SG and the word line WL1 or the distance d1′ between the select gate SG and the word line WL1′ may be accurately controlled.

Although the above embodiments take a flash memory as an example to illustrate a series of patterning steps, the disclosure is not limited thereto. In other embodiments, these patterning steps may also be used to form a dynamic random access memory (DRAM) or a similar target layer/film.

In embodiments of the disclosure, the loading effect may be lowered or avoided during etching of the target layer, and the distances between the select gate and the word lines may be accurately controlled. Therefore, when the memory device is programmed, the GIDL effect caused by the gate string, the select gate leakage current and electrons that are injected into the floating gate corresponding to the word line adjacent to the select gate may be slowed down or suppressed.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device, comprising:
a substrate;
a plurality of word lines located above the substrate;
a select gate located on one side of the word lines; and
a dummy word line located between the word lines and the select gate,
wherein a first gap between the word lines has a first gap width, a second gap between the dummy word line and an edge word line of the word lines has a second gap width, a third gap between the dummy word line and the select gate has a third gap width, and a ratio of the third gap width to the first gap width is between 0.95 and 1.05.

2. The memory device according to claim 1, wherein a width of the dummy word line is greater than a width of each of the word lines.

3. The memory device according to claim 2, wherein a ratio of the width of the dummy word line to the width of each of the word line is between 1.1 and 2.5.

4. The memory device according to claim 1, wherein a ratio of the second gap width to the first gap width is between 0.95 and 1.05.

5. The memory device according to claim 1, wherein the second gap width is equal to the first gap width.

6. The memory device according to claim 1, further comprising:
a dummy comb and a plurality of dummy pillars adjacent to the word lines, the dummy word line, and a plurality of ends of the select gate.

7. The memory device according to claim 6, wherein the dummy comb comprises:
a body; and
a plurality of extending portions located between the body and the word lines and connected to the body.

8. The memory device according to claim 7, wherein the dummy pillars are located between the body and the word lines.

9. The memory device according to claim 8, wherein the dummy pillars and the extending portions are disposed in an alternating manner.

10. The memory device according to claim 7, wherein the dummy pillars and the extending portions are disposed in a manner corresponding to the word lines, the dummy word line, and the select gate.

11. A method of fabricating a memory device, comprising:
providing a substrate;
forming a target layer on the substrate;
forming a sacrificial layer on the target layer;
forming a core layer on the sacrificial layer;
forming a plurality of gap walls on a plurality of side walls of the core layer;
removing the core layer;
treating the gap walls as a mask and patterning the sacrificial layer to form a patterned sacrificial layer;
forming a hard mask layer between the patterned sacrificial layer;
removing the patterned sacrificial layer; and
treating the hard mask layer as a mask and patterning the target layer to form a plurality of word lines, a dummy word line, and a select gate, wherein the dummy word line is located between the word lines and the select gate.

12. The method of fabricating the memory device according to claim 11, wherein a width of the dummy word line is greater than a width of each of the word lines.

13. The method of fabricating the memory device according to claim 12, wherein a ratio of the width of the dummy word line to the width of each of the word lines between 1.1 and 2.5.

14. The method of fabricating the memory device according to claim 11, wherein a first gap between the word lines has a first gap width, a second gap between the dummy word line and an edge word line of the word lines has a second gap width, and a ratio of the second gap width to the first gap width is between 0.95 and 1.05.

15. The method of fabricating the memory device according to claim 11, wherein a third gap between the dummy word line and the select gate has a third gap width, wherein a ratio of the third gap width to the first gap width is between 0.95 and 1.05.

16. The method of fabricating the memory device according to claim 11, wherein a third gap between the dummy word line and the select gate has a third gap width, and the third gap width is equal to the second gap width.

17. The method of fabricating the memory device according to claim 11, further comprising:
partially removing the hard mask layer to expose part of the target layer.

18. The method of fabricating the memory device according to claim 17, wherein the treating the hard mask layer as a mask and patterning the target layer further comprises:
forming a dummy comb and a plurality of dummy pillars adjacent to the word lines, the dummy word line, and a plurality of ends of the select gate, wherein the dummy comb comprises:
a body; and
a plurality of extending portions located between the body and the word lines and connected to the body.

19. The method of fabricating the memory device according to claim 18, wherein the dummy pillars are located between the body and the word lines, and the dummy pillars and the extending portions are disposed in an alternating manner.

20. The method of fabricating the memory device according to claim 18, wherein the dummy pillars and the extending portions are disposed in a manner corresponding to the word lines, the dummy word line, and the select gate.
